(19) United States
(12) Patent Application Publication
(10) Pub. No.: US 2006/0132198 A1
(43) Pub. Date: Jun. 22, 2006

(54) Above rail writer driver

(76) Inventors: Reza Sharifi, Plano, TX (US); Indumini Ranmather, Plano, TX (US)

Correspondence Address: TEXAS INSTRUMENTS INCORPORATED, P O BOX 655474, M/S 3999, DALLAS, TX, 75265, US

(21) Appl. No.: 11/021,054

(22) Filed: Dec. 22, 2004

(51) Int. Cl. H03B 1/00

(52) U.S. Cl. 327/110

(57) ABSTRACT

The present invention achieves technical advantages as a write driver preamplifier circuit providing a higher output voltage than that of the supply voltage, and utilizing smaller capacitors. The circuit generates a differential voltage across the writer output larger than the supply voltage. Advantageously, during the DC portion of the write current, such as when HWX and HWY are almost at ground, small capacitors are each charged by a capacitive driver to half of the total supply voltage. When the writer toggles, the capacitor drivers switch the capacitors from one supply to the other supply. As the capacitors discharge, the voltage decreases and then the capacitors are charged with the opposite polarity.

### FIELD OF THE INVENTION

The present invention is generally related to power supplies, and more particularly to preamplifiers in write driver circuits for high performance mobile hard disk drives.

### BACKGROUND OF THE INVENTION

As the density and speed of hard disk drives increases, write driver circuit preamplifiers need to launch larger voltages to achieve the required rise time and overshoot of write signals, and still operate with smaller voltage and lower power. Conventionally, to achieve a larger voltage in a hard disk drive preamplifier circuit, charge pumps are utilized which require large capacitors, and which are not power efficient. Further, due to lower supply voltage requirements, conventional writer driver performances are not adequate for high data rate applications.

There is desired a write driver preamplifier circuit adapted to provide a larger output voltage that is suitable for high data rate applications, which solution only requires small supply voltage/small capacitors and has a lower impact on power.

### SUMMARY OF THE INVENTION

The present invention achieves technical advantages as a write driver preamplifier circuit providing a higher output voltage than that of the supply voltage, and utilizing smaller capacitors. The circuit generates a differential voltage across the writer output larger than the supply voltage. Advantageously, during the DC portion of the write current, such as when HWX and HWY are almost at ground, small capacitors are each charged by a capacitive driver to half of the total supply voltage. When the writer toggles, the capacitor drivers switch the capacitors from one supply to the other supply. As the capacitors discharge, the voltage decreases and then the capacitors are charged with the opposite polarity.

### BRIEF DESCRIPTION OF THE DRAWINGS

FIG. 1 is a simplified schematic diagram of one embodiment of the invention;

FIG. 2A-2C show different implementations of current sources;

FIG. 3A-3C show different implementations of capacitor drivers;

FIG. 4A-4C show different implementations of output driver impedance matching;

FIG. 5 is a detailed electrical schematic of a write driver according to one embodiment of the present invention;

FIG. 6 is a graph of the voltages at nodes HWX and HWY depicting a transient response;

FIG. 7 is a graph of the current provided to the head at input WHX;

FIG. 8 is a graph of the transient response of FET MN3;

FIG. 9 is a graph of the transient response of MOSFET MN6;

FIG. 10 is a graph of the transient response of FET MP0;

FIG. 11 is a graph of the transient response of MOSFET MP9;

FIG. 12 is a graph of the transient response of transistor MP4;

FIG. 13 is a graph of the transient response of FET MN0; and

FIG. 14 is a graph of the transient response of FET MN11.

### DETAILED DESCRIPTION OF THE PREFERRED EMBODIMENT

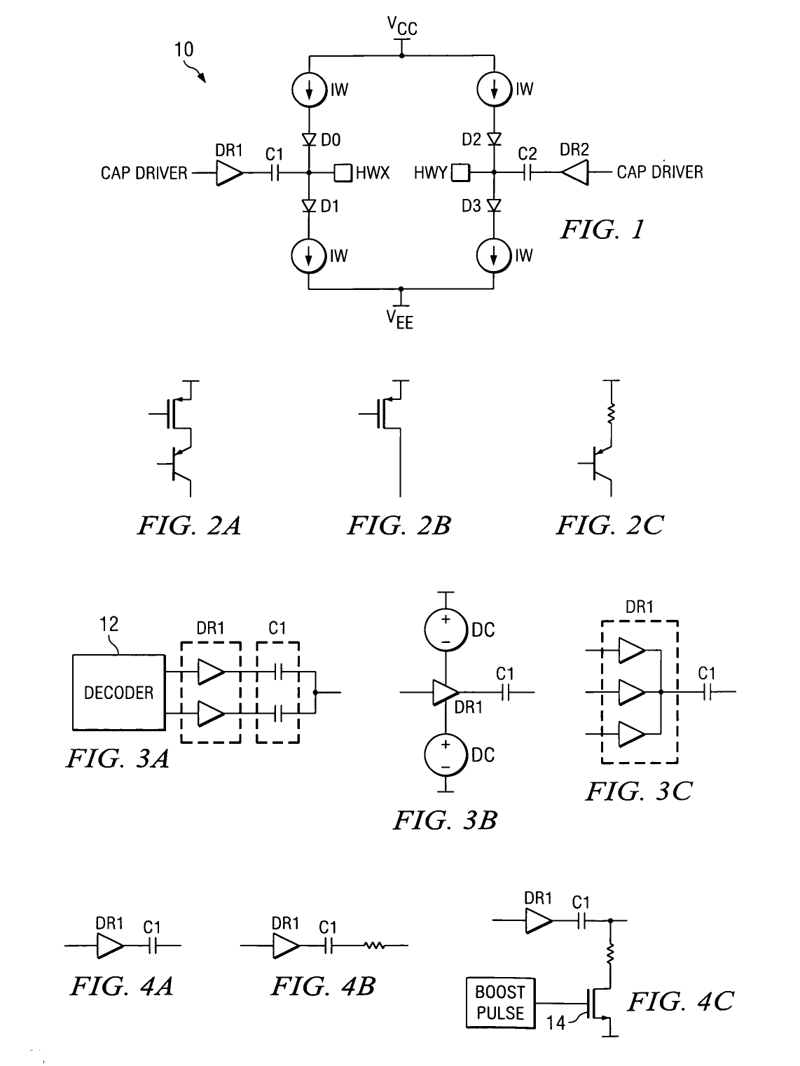

Referring now to FIG. 1, there is shown at 10 a simplified schematic diagram of one embodiment of the present invention at 10 seen to comprise a write driver circuit. The current sources IW generate the IWDC. The capacitors C1 and C2 and the corresponding capacitor drivers DR1 and DR2 create the write current overshoot. During the DC portion of the write current, when nodes HWX and HWY of the H-bridge are almost at ground, each capacitor C1 and C2 charges to half of the upper supply voltage VCC. When the writer 10 toggles, the capacitor drivers DR1 and DR2 switch the capacitors C1 and C2 from the upper supply VCC to the other supply VEE. Advantageously, the writer 10 generates a differential voltage across the writer output, HWX and HWY which is larger than the supply voltage VCC-VEE. As the capacitors C1 and C2 discharge, the voltage across the output HWX-HWY decreases, and the capacitors Cl and C2 charge with the opposite polarity.

The diodes D0, D1, D2, D3 protect the DC current sources IW during the write current overshoot, and also make sure that no current flows from the capacitors through these devices to the supply voltages VCC and VEE.

FIG. 2A, FIG. 2B, and FIG. 2C shown three different possible implementations of current sources, although others may be used as well, and hence limitations to the configuration of the current sources is not to be inferred in the invention.

Advantageously, circuit 10 also controls the write driver current overshoot amplitude. FIG. 3A, FIG. 3B and FIG. 3C show three different possible implementations for each capacitor driver doing this. FIG. 3A shows a first method having multiple capacitors and corresponding drivers, and this method depends on how many of the capacitors are switched by a decoder 12 to obtain various overshoots. FIG. 3B shows a method of using a variable voltage to the capacitor driver's supply lines, and FIG. 3C shows a third option of using only different size drivers.

The output of the write driver circuit 10 is also matched to the flex (Rmatch) to minimize reflection and jitter. FIGS. 4A, 4B, and 4C show three different possible embodiments to achieve this. FIG. 4A shows an approach whereby just the resistance of each capacitor driver is relied on. FIG. 4B shows an embodiment using a series resistor with the capacitor which limits the maximum current overshoot. FIG. 4C shows an approach having a resistor coupled to ground with a switch 14 in series between the resistor and ground, which switch is open during overshoot to make sure there is no leakage current through the resistor during an overshoot condition.

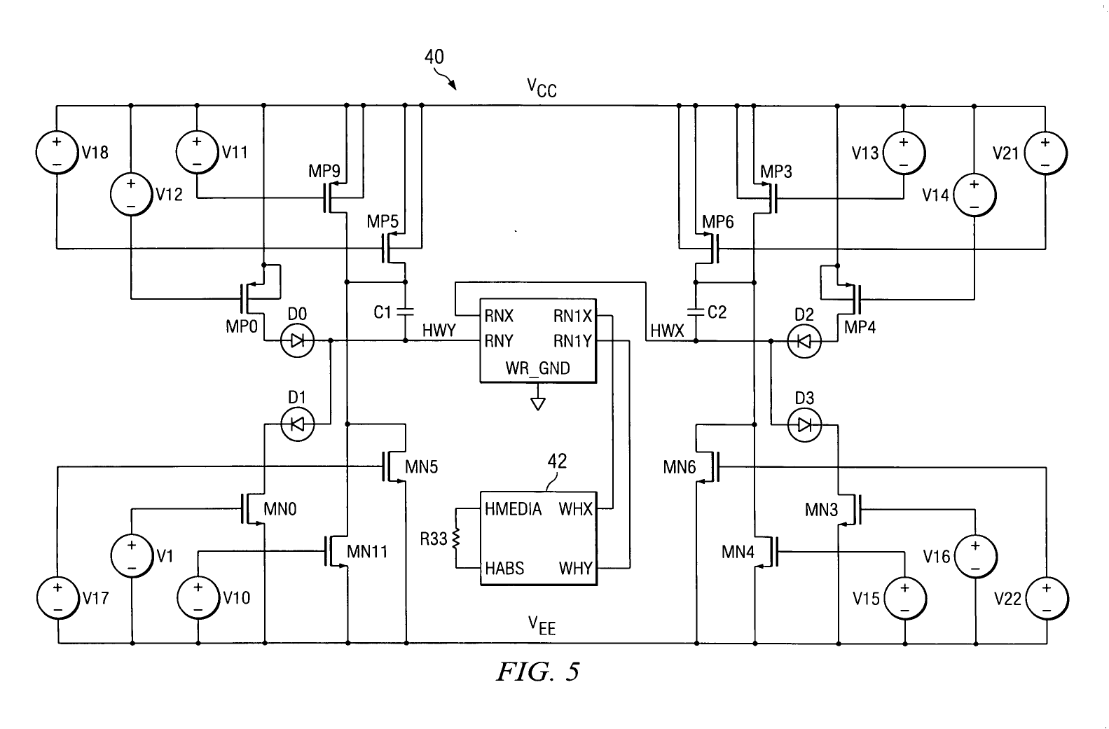

Referring now to FIG. 5, there is shown a detailed electrical schematic of one embodiment of the present invention at 40 corresponding to block diagram 10 in FIG. 1.

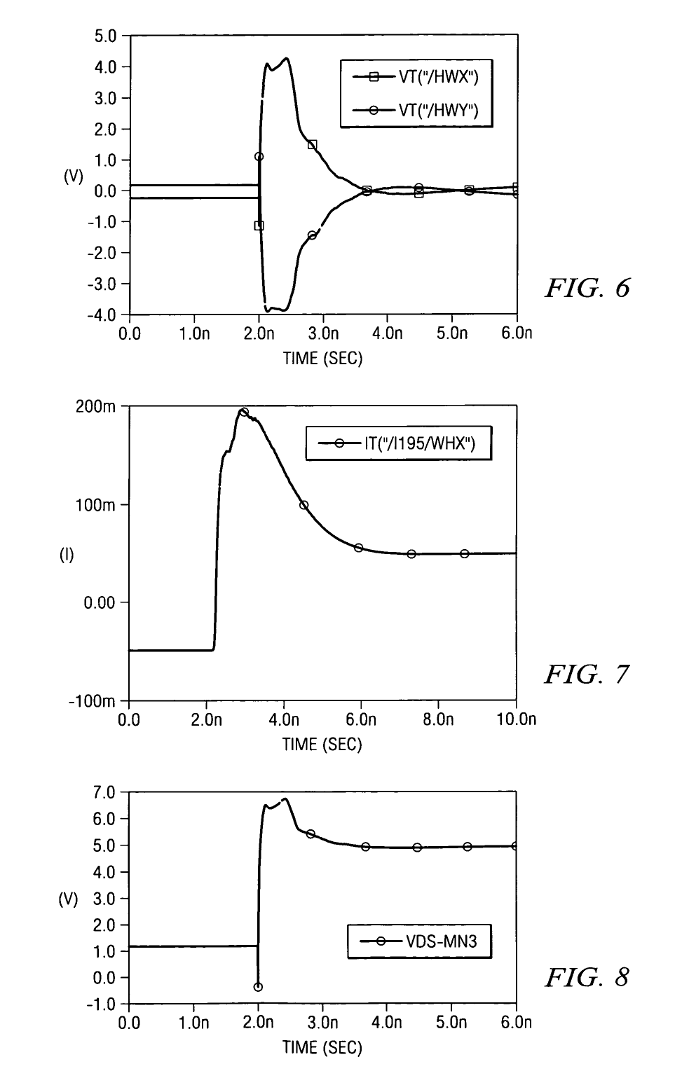

FIG. 6 depicts the differential transient response across outputs HWX and HWY of the H-bridge, and illustrates the controlled and fast transient response thereacross.

FIG. 7 depicts the transient response of the write current provided to input WHX of a write head denoted at 42.

FIG. 8 depicts the transient response across the drain and source of MOSFET MN3.

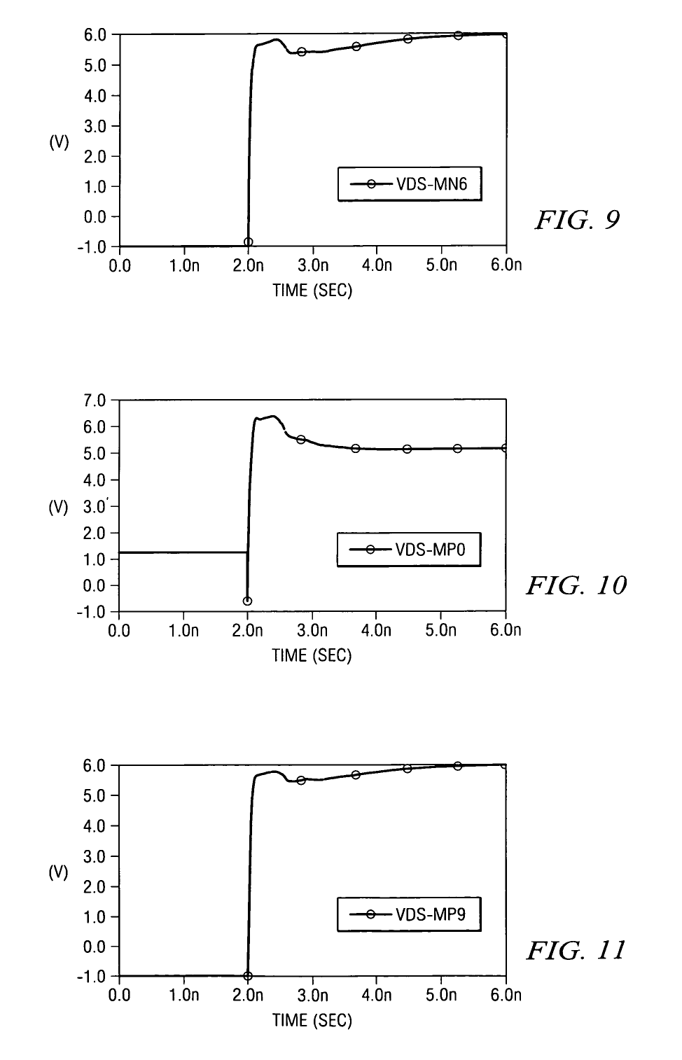

FIG. 9 depicts the transient response across the drain and source of MN6.

FIG. 10 depicts the transient response across the drain and source of MP0.

FIG. 11 depicts the transient response across the drain and source of MP9.

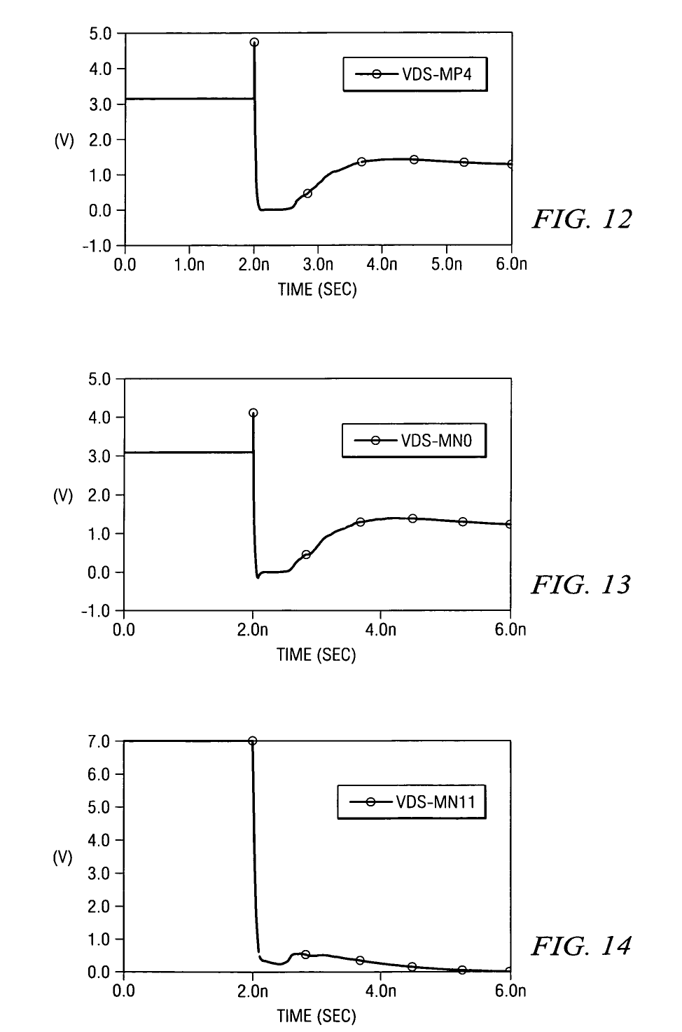

FIG. 12 depicts the transient response across the drain and source of MP4.

FIG. 13 depicts the transient response across the drain and source of MN0.

FIG. 14 depicts the transient response across the drain and source of MN11.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

We claim:

1. A circuit comprising:
a driver circuit having an output and comprising an H-bridge operating from a differential voltage provided by a differential supply; and
a boost circuit coupled to the driver circuit including a first and second capacitor driven by a respective capacitor driver and generating a differential write current and a differential output voltage across the driver circuit output, the differential output voltage being greater than the differential supply voltage.

2. The circuit as specified in claim 1 wherein the capacitors create an overshoot in the differential write current.

3. The circuit as specified in claim 2 wherein during a DC portion of the differential write current the capacitors are each charged to less than the differential supply voltage.

4. The circuit as specified in claim 3 wherein each of the capacitors is charged to about half of the differential supply voltage during the write current DC portion.

5. The circuit as specified in claim 3 wherein the driver circuit toggles between providing a positive and negative said differential write current, wherein during toggling the driver circuit switches the capacitors to charge from the other supply voltage of the differential supply voltage.

6. The circuit as specified in claim 5 wherein each of the capacitors are discharged during the toggling, and then the capacitors are each charged with the other supply voltage.

7. The circuit as specified in claim 2 wherein the driver circuit H-bridge comprises a plurality of current sources and a plurality of diodes protecting the current sources during the current overshoot, and also preventing current from flowing from each of the capacitors to the differential supply.

8. The circuit as specified in claim 2 wherein the current overshoot amplitude is controlled by a control circuit.

9. The circuit as specified in claim 8 wherein each capacitor driver comprises multiple drivers each being selectively driving one of the capacitors.

10. The circuit as specified in claim 8 wherein each of the capacitor drivers is powered by a variable voltage.

11. The circuit as specified in claim 1 wherein each of the capacitor drivers has a driver resistance affecting an output impedance of the driver circuit.

12. The circuit as specified in claim 1 wherein each of the capacitor drivers includes a resistor and capacitor limiting the current overshoot.

13. The circuit as specified in claim 1 wherein each of the capacitor drivers includes a plurality of resistors coupled to ground by a switch controlling leakage current through the resistors during the overshoot.
